(19) United States
(12) Patent Application Publication
(10) Pub. No.: US 2016/0026089 A1
(43) Pub. Date: Jan. 28, 2016

(54) MASK PLATE AND MANUFACTURING METHOD THEREOF

(71) Applicants: BOE TECHNOLOGY GROUP CO., LTD., Beijing (CN); ORDOS YUANSHENG OPTOELECTRONICS CO., LTD., Inner Mongolia (CN)

(72) Inventor: Junsheng CHEN, Beijing (CN)

(73) Assignees: BOE TECHNOLOGY GROUP CO., LTD., Beijing (CN); ORDOS YUANSHENG OPTOELECTRONICS CO., LTD., Ordos (CN)

(21) Appl. No.: 14/422,653

(22) PCT Filed: Apr. 17, 2014
(86) PCT No.: PCT/CN2014/075547

§ 371 Date: Feb. 19, 2015

(30) Foreign Application Priority Data
Dec. 30, 2013 (CN) 201310745048.0

(51) Int. Cl. G03F 7/40; B05B 15/04; G03F 7/30; H01L 51/56; G03F 7/16; G03F 7/20

(52) U.S. Cl. CPC G03F 7/40; G03F 7/16; G03F 7/20; G03F 7/3007; H01L 51/56; B05B 15/045

(57) ABSTRACT

An embodiment of the present disclosure provides a mask plate and a manufacturing method thereof. The present disclosure belongs to the field of organic electroluminescence device manufacturing, and aims to improve a quality of a pattern generated during an evaporation process. The mask plate includes a pattern region and an auxiliary region positioned at an outer periphery of the pattern region. At least a part of the auxiliary region has a thickness larger than a thickness of the pattern region. The embodiment of the present disclosure can be applied to a manufacturing of an organic electroluminescence device.

### TECHNICAL FIELD

The embodiment of the present disclosure relates to the field of organic electroluminescence device manufacturing, in particular to a mask plate and a manufacturing method thereof.

### BACKGROUND

AMOLED (Active Matrix/Organic Light Emitting Diode) is an active matrix organic light emitting diode panel. Compared with a conventional liquid crystal panel, AMOLED has a faster response speed, higher contrast ratio, and a wide view angle. Thus, AMOLED is considered as a most promising next-generation display panel.

During an evaporation of AMOLED product, a metal mask plate is used in a fine metal mask preparation process. An improvement to the mask plate is continuously carried out to make the mask plate thinner and thinner so that PPI (Pixels per inch) of the AMOLED product can break the current level and the display screen can provide a finer display performance.

However, since most material of the metal mask plate is invar alloy, which has a substantially low thermal expansion coefficient, the mask plate usually has a thickness of 40 μm. When the mask plate is used after the thickness of the mask plate is reduced, the inventors have found the following problem. As shown in FIG. 1, when the thinned metal mask plate is welded on a metal frame by stretching technique for evaporation, normal fractures shown in FIG. 1A easily deform in fracture extending directions as the fractures shown in FIG. 1B in the subsequent heating process. This deformation directly affects a quality of a pattern that is generated by the AMOLED product during the evaporation.

Thus, a mask plate, which can provide an improved evaporation effect during the evaporation process, is needed so that a deformation of the mask plate, which affects the evaporation effect of the AMOLED product, is suppressed.

### SUMMARY

It is an object of the embodiments of the present disclosure to provide a mask plate and a manufacturing thereof, each of which improves a quality of a pattern that is generated by the evaporation process.

In order to achieve above-described purpose, embodiments of the present disclosure adopt the following technical solution.

A mask plate includes a pattern region and an auxiliary region positioned at an outer periphery of the pattern region. At least a part of the auxiliary region has a thickness larger than a thickness of the pattern region.

Further, the at least a part of the auxiliary region whose thickness is larger than the thickness of the pattern region has a closed shape or a semi-closed shape.

Alternatively, the pattern region has a rectangular shape, and the at least a part of the auxiliary region having the semi-closed shape is positioned at an outer side of four corners of the pattern region, and the at least a part of the auxiliary region has at least one of an L-shape, a T-shape, or a cross shape.

Alternatively, multiple metal mask plates are used as one metal mask plate. An L-shaped pattern having a different direction is formed at a portion where only one corner is positioned, a T-shaped pattern having a different direction is formed at a portion where two adjacent corners are positioned, and a cross-shaped pattern is formed at a portion where four adjacent corners are positioned.

Alternatively, the pattern region has a rectangular shape, and the at least a part of the auxiliary region having the closed shape is positioned at an outer side of the pattern region, and the at least a part of the auxiliary region has a rectangular-shaped pattern.

A manufacturing method of the mask plate according to any one of above-described technical solutions includes:
preparing a first sheet;
forming the pattern region and the auxiliary region on the first sheet, the auxiliary region being positioned at the outer periphery of the pattern region; and
processing the auxiliary region so that the at least a part of the auxiliary region has a thickness larger than a thickness of the pattern region.

The forming of the pattern region and the auxiliary region that is positioned at the outer periphery of the pattern region on the first sheet includes:
patterning a pattern portion of the first sheet and forming the pattern region on the pattern portion of the first sheet; and
forming the auxiliary region at a portion other than the pattern portion on the first sheet.

Further, the mask plate is a metal mask plate. The processing of the auxiliary region so that at least a part of the auxiliary region has the thickness larger than the thickness of the pattern region includes:
coating the auxiliary region and the pattern region with a photoresist;
exposing the auxiliary region coated with the photoresist using a first mask plate to form a photoresist removing region and a photoresist remaining region of the photoresist, the photoresist removing region corresponding to the at least a part of the auxiliary region which has the thickness larger than the thickness of the pattern region and the photoresist remaining region corresponding to a remaining part of the auxiliary region and the pattern region;
removing the photoresist of the photoresist removing region to form a first electroforming substrate having a pattern identical to a pattern of the first mask plate;
performing an electroforming processing to the first electroforming substrate for growing a metal layer at the photoresist removing region by electroforming so that the at least a part of the auxiliary region has the thickness larger than the thickness of the pattern region; and
removing the photoresist of the photoresist remaining region.

The performing of the electroforming processing to the electroforming substrate for growing the metal layer at the photoresist removing region by electroforming includes:
placing the first electroforming substrate into an electroforming tank filled with an electroforming solution; and
electrifying the electroforming tank to grow an electroforming metal material included in the electroforming solution with the first electroforming substrate as a growing substrate until a thickness of the metal layer grown on the first electroforming substrate becomes a required thickness.

Alternatively, the electroforming metal material is an invar alloy or an iron.

Alternatively, the required thickness is 10 μm to 50 μm.

Alternatively, the pattern portion is a predetermined portion of the first sheet on which the pattern of the mask plate is to be formed.

A manufacturing method of the mask plate according to any one of above-described technical solutions includes:
preparing a second sheet;
forming the pattern region and the auxiliary region on the second sheet, the auxiliary region being positioned at the outer periphery of the pattern region; and
thinning the entire pattern region and a part of the auxiliary region so that the at least a part of the auxiliary region has the thickness larger than the thickness of the pattern region or thinning the entire pattern region so that the auxiliary region has the thickness larger than the thickness of the pattern region.

Further, the thinning of the entire pattern region and a part of the auxiliary region so that the at least a part of the auxiliary region has the thickness larger than the thickness of the pattern region includes:
coating the pattern region and the auxiliary region with a photoresist;
exposing the pattern region and the auxiliary region coated with the photoresist using a second mask plate to form a photoresist removing region and a photoresist remaining region, the photoresist remaining region corresponding to the at least a part of the auxiliary region and the photoresist removing region corresponding to the pattern region and a remaining part of the auxiliary region;
removing the photoresist of the photoresist removing region;
thinning the photoresist removing region by etching so that the thickness of the at least a part of the auxiliary region is thicker than the thickness of the pattern region; and
removing the photoresist of the photoresist remaining region.

Further, the thinning of the entire pattern region so that the auxiliary region has the thickness larger than the thickness of the pattern region includes:
coating the pattern region and the auxiliary region with photoresist;
exposing the pattern region and the auxiliary region coated with the photoresist using a second mask plate to form a photoresist removing region and a photoresist remaining region, the photoresist remaining region corresponding to the auxiliary region and the photoresist removing region corresponding to the pattern region;
removing the photoresist of the photoresist removing region;
thinning the photoresist removing region by etching so that the thickness of the auxiliary region is larger than the thickness of the pattern region; and
removing the photoresist of the photoresist remaining region.

Alternatively, a thickness of the second sheet is 50 μm to 100 μm.

The embodiment of the present disclosure provides a mask plate and a manufacturing method thereof. Compared with a current mask plate, the mask plate provided by the embodiment of the present disclosure thickens auxiliary region at a portion other than the pattern region so that the at least a part of the auxiliary region has a thickness thicker than a thickness of the pattern region. By thickening the auxiliary region, the generated mask plate that is welded on a metal frame by stretching technical for evaporation can effectively avoid a deformation of fracture included in the mask plate in a fracture extending direction during the following heating process. Accordingly, a quality of a pattern generated during the evaporation processing can be improved.

### BRIEF DESCRIPTION OF THE DRAWINGS

FIG. 1 is a diagram showing a mask plate according to a prior art;

FIG. 2 is a diagram showing a mask plate according to an embodiment of the present disclosure;

FIG. 3 is a flowchart showing a manufacturing method of a mask plate according to an embodiment of the present disclosure; and

FIG. 4 is a flowchart showing another manufacturing method of a mask plate according to an embodiment of the present disclosure.

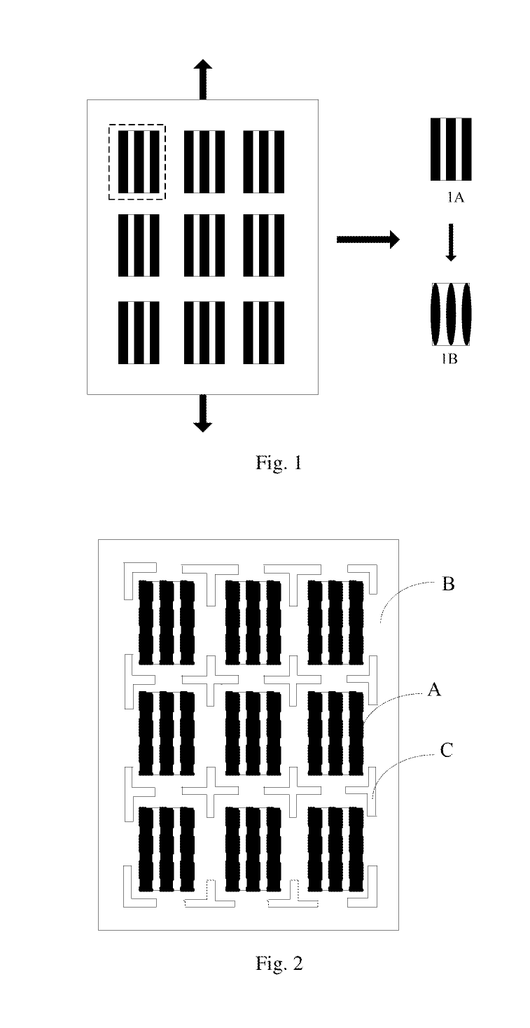

### DETAILED DESCRIPTION

To make the objects, the technical solutions and the advantages of the present disclosure more apparent, the following will describe the present disclosure with reference to specific embodiments and accompanying drawings. Obviously, the embodiments described in the following are merely partial embodiments of the present disclosure, but not the entire embodiments. Based on the embodiments of the present disclosure described below, other embodiments that could have been easily made by a person skilled in the art without any inventive efforts are also included in a protection scope of the present disclosure.

The following will describe a mask plate and a manufacturing method of the mask plate according to an embodiment of the present disclosure in detail with reference to the drawings.

The embodiment of the present disclosure provides a mask plate. As shown in FIG. 2, the mask plate includes a pattern region A and an auxiliary region B. The auxiliary region B is positioned at an outer periphery of the pattern region A. At least a part C of the auxiliary region B has a thickness that is larger than a thickness of the pattern region A.

The embodiment of the present disclosure provides a mask plate. Compared with a conventional mask plate, the mask plate provided by the embodiment of the present disclosure thickens auxiliary region at a portion other than the pattern region so that the at least a part of the auxiliary region has a thickness larger than a thickness of the pattern region. By thickening the auxiliary region, the generated mask plate that is welded on a metal frame by stretching technical for evaporation can effectively avoid a deformation of fracture included in the mask plate in a fracture extending direction during the following heating process. Accordingly, a quality of a pattern generated during the evaporation processing can be improved.

A material of above-described mask plate may have various options. For example, the material may be metal, stainless steel, or glass.

The following will describe a metal mask plate as an example.

In the present embodiment, in the auxiliary region B, the at least a part C of the auxiliary region B whose thickness is larger than the thickness of the pattern region has a closed shape or a semi-closed shape. In order to provide a better reinforcement, a pattern of the auxiliary region B positioned at the outer side of the pattern region A can be selected based on actual production needs. That is, the pattern may be a closed shape, or may be a semi-closed shape. When adopting the semi-closed shape, an outer side of each of four corners of the pattern region can be thickened. In the present embodiment, preferably, the semi-closed shape is adopted. By thickening the auxiliary region at the outer side of each of four corners of the pattern region, the deformation of the fracture included in the pattern region can be suppressed during the heat treatment processing of the evaporation.

Alternatively, the pattern region has a rectangular shape. The at least a part of the auxiliary region having the semi-closed shape is positioned at the outer side of each of four corners of the pattern region, and has at least one of an L-shape, a T-shape, or a cross shape. When adopting the semi-closed shape and thickening the auxiliary region at the outer side of four corners of the pattern region, in the mask plate including multiple pieces of a metal mask plate, an L-shaped pattern having a different direction is formed at a portion where only one corner of the metal mask plate is positioned, a T-shaped pattern having a different direction another is formed at a portion where two adjacent corners of the metal mask plates are positioned, and a cross-shaped pattern is formed at a portion where four adjacent corners of the metal mask plates are positioned. When adopting the semi-closed shape, not only the auxiliary region positioned at the outer side of each of four corners of the pattern region can be thickened, but also a portion other than the outer side of each of four corners of the pattern region can be thickened. The purpose of above-described thickening is to suppress the deformation of the fracture of the metal mask plate in the fracture extending direction during the heat treatment of the evaporation process. It should be noted that in order to make a shape of the product acquired by the evaporation have a regular pattern, in the present embodiment, the pattern region may have a rectangular shape. The pattern region may also have different shapes, such as a polygonal shape, a circular shape, a trapezoidal shape according to a shape of the product generated by the evaporation. The shape of the pattern region is not limited to above-described examples.

Alternatively, at least a part of the closed shape is positioned at the outer side of the pattern region, and has a rectangular pattern. The pattern region has a rectangular shape. Thus, when thickening the entire auxiliary region positioned at the outer side of the pattern region, the auxiliary region of the pattern region also has the rectangular pattern.

The embodiment of the present disclosure further provides a manufacturing method of the mask plate provided by the above-described embodiment.

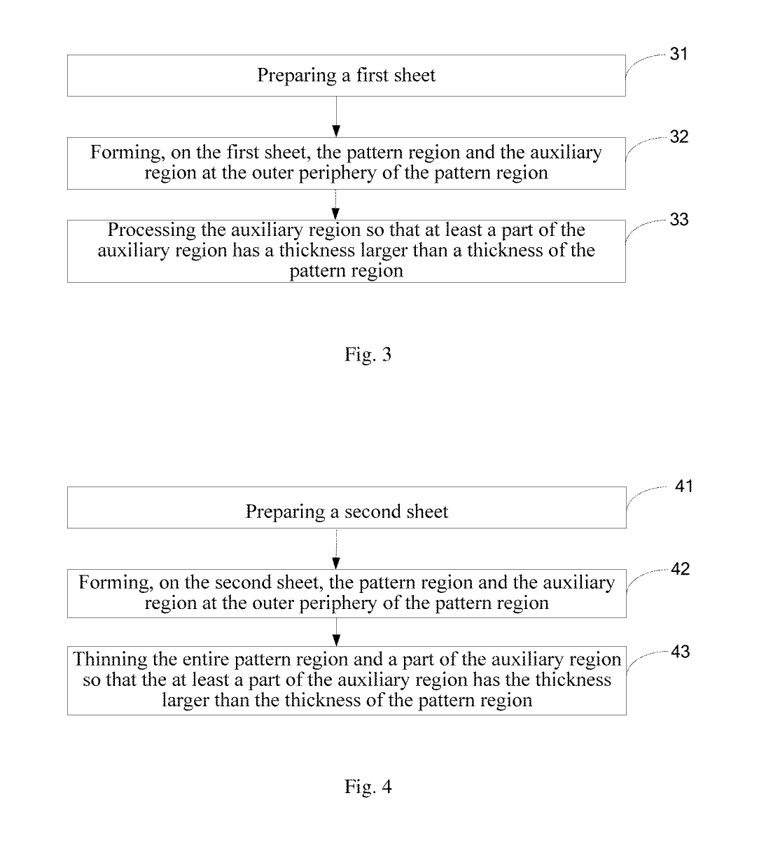

As shown in FIG. 3, the manufacturing method includes:
a step 31: preparing a first sheet;
a step 32: forming the pattern region and the auxiliary region on the first sheet, the auxiliary region being positioned at the outer periphery of the pattern region; and
a step 33: processing the auxiliary region so that at least a part of the auxiliary region has a thickness larger than a thickness of the pattern region.

The embodiment of the present disclosure provides a manufacturing method of the mask plate. In this manufacturing method, at least a part of the auxiliary region has the thickness larger than the thickness of the pattern region by processing the auxiliary region of the metal mask plate at a portion other than the pattern region. The mask plate obtained by above-described manufacturing method provides the following advantage. When the generated mask plate is welded on a metal frame by stretching technical for evaporation, a deformation of fracture included in the mask plate in a fracture extending direction during the following heat treatment processing can be effectively avoided. Accordingly, a quality of a pattern generated during the evaporation processing can be improved.

In the step 32, the forming of the pattern region A and the auxiliary region B at the outer periphery of the pattern region A on the first sheet includes:
patterning a pattern portion of the first sheet and forming the pattern region Aon the pattern portion of the first sheet; and
forming, on the first sheet, the auxiliary region at the outer periphery of the pattern region at a portion other than the pattern portion.

The pattern portion is a predetermined portion of the metal sheet on which the pattern of the mask plate is to be formed. For example, in the manufacturing method of the mask plate to be used for producing a display panel, the pattern portion is a predetermined region on the first sheet where the mask plate pattern to be formed. For a mask plate to be used for patterning a parent substrate, since the mask processing needs to produce patterns of multiple display panels (or single panel) at a time, the first sheet has multiple pattern portions corresponding to respective panels. Correspondingly, after patterning the first sheet, multiple above-described pattern portions form the pattern regions of the mask plate that correspond to respective panels. That is, the pattern portions and the pattern regions correspond to the same region. Herein, the pattern portion is a corresponding part on the first sheet on which the pattern is not formed, and the pattern region is a corresponding part on the mask plate on which the pattern is formed. As shown in FIG. 2, the pattern region A of the mask plate is usually positioned at a central portion of each corresponding panel region, and the auxiliary region B of the mask plate is usually positioned surrounding portion of each corresponding panel region.

In the present step, first, the pattern region and the auxiliary region positioned at the outer side of the pattern region are formed on the first sheet by pattering process. That is, the first sheet is coated with photoresist, exposed, developed, and etched in order. After the etching, remaining photoresist is removed so that the pattern region A is formed in the pattern portion of the first sheet and the auxiliary region is formed at the outer side of the pattern region at the same time.

Further, in the step 33, the mask plate is a metal mask plate. The processing of the auxiliary region so that at least a part of the auxiliary region has the thickness larger than the thickness of the pattern region includes:
coating the auxiliary region and the pattern region with a photoresist;
exposing the auxiliary region coated with the photoresist using a first mask plate to form a photoresist removing region and a photoresist remaining region of the photoresist, the photoresist removing region corresponding to the at least a part of the auxiliary region which has the thickness larger than the thickness of the pattern region and the photoresist remaining region corresponding to a remaining part of the auxiliary region and the pattern region;
removing the photoresist of the photoresist removing region to form a first electroforming substrate having a pattern identical to a pattern of the first mask plate;
performing an electroforming processing to the electroforming substrate for growing a metal layer at the photoresist removing region by electroforming so that the at least a part of the auxiliary region has the thickness larger than the thickness of the pattern region; and
removing the photoresist of the photoresist remaining region.

In the present step, the auxiliary region is thickened by the electroforming process. In order to obtain the metal mask plate in which the at least a part of the auxiliary region has the thickness larger than the thickness of the pattern region, the first electroforming substrate that matches with the pattern needs to be prepared at first. That is, coating the auxiliary region with the photoresist and carrying out exposure using the first mask plate. After removing the photoresist of the photoresist removing region, the first electroforming substrate having the same pattern with the first mask plate can be obtained. Then, the portion of the first electroforming substrate from which the photoresist has been removed is grown using electroforming processing for generating the at least a part of the auxiliary region having the thickness larger than the thickness of the pattern region. When the photoresist coated to the auxiliary region and the pattern region is a positive photoresist, the photoresist removing region corresponds to an exposing region and the photoresist remaining region corresponds to a non-exposing region. When the photoresist coated to the auxiliary region and the pattern region is a negative photoresist, the photoresist removing region corresponds to a non-exposing region and the photoresist remaining region corresponds to an exposing region. It should be noted that the first mask plate is different from the mask plate provided by the embodiment of the present disclosure. The first mask plate is an intermediately used mask plate in order to manufacture the mask plate according to the embodiment of the present disclosure.

The performing of the electroforming processing to the first electroforming substrate for growing the metal layer at the photoresist removing region by electroforming includes:
placing the first electroforming substrate into an electroforming tank filled with an electroforming solution; and
electrifying the electroforming tank to growing an electroforming metal material included in the electroforming solution with the first electroforming substrate as a growing substrate until a thickness of the metal layer grown on the first electroforming substrate becomes a required thickness.

In the present step, using the electroforming principle, the portion of the first electroforming substrate from which the photoresist has been removed is grown using the electroforming processing method. The principle of electroforming is described as below. First, placing the first electroforming substrate that is preliminarily shaped into a required shape into the electroforming metal material solution as a cathode and placing the electroforming material as an anode together with the first electroforming substrate into the electroforming metal material solution, which has the same composition with the electroforming material of the anode. Then, a direct current is electrified through the solution. Under electrolytic action, a metal layer is gradually deposited on a surface of the first electroforming substrate. When the thickness of the metal layer becomes a required thickness, the first electroforming substrate is taken out from the solution. Then, the metal layer is separated from the first electroforming substrate in order to obtain a metal member having an opposite shape with the first electroforming substrate.

The electroforming metal material should be the same with the anode material, that is should be the same with the material of the first electroforming substrate. Alternatively, the electroforming metal material may be an invar alloy or an iron. In order to manufacture a finer display panel during the evaporation processing, the metal material for manufacturing the metal mask plate usually adopts the invar alloy having a low thermal expansion coefficient. However, the invar alloy has a low strength and a low rigidity. Thus, in the embodiment of the present disclosure, the at least a part of the auxiliary region has the thickness larger than the thickness of the pattern region. This is important for avoiding the deformation of the fracture included in the mask plate in the fracture extending direction.

In order to obtain the pattern in which the at least a part of the auxiliary region has the thickness larger than the thickness of the pattern region, the thickness difference between the thickness of the at least a part of the auxiliary region and the pattern region is equal to the thickness of the metal layer. Herein, the metal layer is obtained by growing the portion of the first electroforming substrate from which the photoresist has been removed by the electroforming process. Alternatively, the required thickness is 10 μm to 50 μm. Preferably, the required thickness may be 25 μm to 30 μm. The metal mask plate manufacturing using this thickness range has a relatively small thickness. Thus, when the metal mask plate is used in the evaporation process, the display panel having finer display performance can be obtained.

The embodiment of the present disclosure further provides another manufacturing method of the mask plate provided by any one of above-described embodiments. As shown in FIG. 4, the manufacturing method includes:
a step 41: preparing a second sheet;
a step 42: forming, on the second sheet, the pattern region and the auxiliary region, the auxiliary region being positioned at the outer periphery of the pattern region; and
a step 43: thinning the entire pattern region and a part of the auxiliary region so that the at least a part of the auxiliary region has the thickness larger than the thickness of the pattern region.

In above-described step 43, the entire pattern region may be thinned so that the auxiliary region has the thickness larger than the thickness of the pattern region. That is, the thickness of the entire auxiliary region is larger than the thickness of the pattern region.

The embodiment of the present disclosure further provides another manufacturing method of a mask plate. This manufacturing method thickens the portion of the auxiliary region other than the pattern region in the mask plate by a thinning method so that the at least a part of the auxiliary region has the thickness larger than the thickness of the pattern region. The mask plate obtained by above-described manufacturing method provides the following advantage. When the manufactured mask plate is welded on a metal frame by stretching technical for evaporation, a deformation of fracture included in the mask plate in a fracture extending direction during the following heat treatment processing can be effectively avoided. Accordingly, a quality of a pattern generated during the evaporation processing can be improved.

Further, in above-described step 43, thinning of the entire pattern region and a part of the auxiliary region so that the at least a part of the auxiliary region has the thickness larger than the thickness of the pattern region includes:
coating the pattern region and the auxiliary region with a photoresist;
exposing the pattern region and the auxiliary region coated with the photoresist using a second mask plate to form a photoresist removing region and a photoresist remaining region, the photoresist remaining region corresponding to the at least a part of the auxiliary region and the photoresist removing region corresponding to the pattern region and a remaining part of the auxiliary region;
removing the photoresist of the photoresist removing region;
thinning the photoresist removing region by etching so that the thickness of the at least a part of the auxiliary region is larger than the thickness of the pattern region.

Correspondingly, in the above-described step 43, the thinning of the entire pattern region so that the auxiliary region has the thickness larger than the thickness of the pattern region includes:
coating the pattern region and the auxiliary region with photoresist;
exposing the pattern region and the auxiliary region coated with the photoresist using a second mask plate to form a photoresist removing region and a photoresist remaining region, the photoresist remaining region corresponding to the auxiliary region and the photoresist removing region corresponding to the pattern region;
removing the photoresist of the photoresist removing region;
thinning the photoresist removing region by etching so that the thickness of the auxiliary region is larger than the thickness of the pattern region; and
removing the photoresist of the photoresist remaining region.

In the present step, first, the pattern region and the auxiliary region are coated with the photoresist at the same time and are exposed using the second mask plate in order to form the pattern region corresponding to the photoresist removing region and other region of the auxiliary region. Then, these regions are thinned by etching in order form the at least a part of the auxiliary region having the thickness larger than the thickness of the pattern region. In the present step, the second sheet is processed using the etching method. Thus, the thickness of the second sheet is relatively thick. Alternatively, the thickness of the second sheet may be approximately 50 μm to 100 μm so that the etching can be carried out by twice in order to obtain the pattern having the required thickness. When the positive photoresist or the negative photoresist is coated to the pattern region and to the auxiliary region, a relation between the photoresist removing region or the photoresist remaining region and the exposing region or the non-exposing region has been described in the above description. Herein, detailed description will be omitted. It should be noted that the second mask plate is different from the mask plate provided by the embodiment of the present disclosure. The second mask plate is an intermediately used mask plate in order to manufacture the mask plate according to the embodiment of the present disclosure.

Apparently, above embodiments are described in order to merely clarify examples described above, but not limit the embodiments of the present disclosure. A person skilled in the art may carry out different changes and modifications based on above-described description. Herein, it is not necessary and is also impossible to describe every embodiment of the present disclosure as an example. Changes or modifications made based on above embodiments of the present disclosure are also in a protection scope of the present disclosure.

What is claimed is:

1. A mask plate comprising:
a pattern region; and
an auxiliary region positioned at an outer periphery of the pattern region,
wherein at least a part of the auxiliary region has a thickness larger than a thickness of the pattern region.

2. The mask plate according to claim 1, wherein
the at least a part of the auxiliary region whose thickness is larger than the thickness of the pattern region has a closed shape or a semi-closed shape.

3. The mask plate according to claim 2, wherein
the pattern region has a rectangular shape, and
the at least a part of the auxiliary region having the semi-closed shape is positioned at an outer side of four corners of the pattern region, and the at least a part of the auxiliary region has at least one of an L-shape, a T-shape, or a cross shape.

4. The mask plate according to claim 3, wherein
a plurality of metal mask plates are used as one metal mask plate,
an L-shaped pattern having a different direction is formed at a portion where only one corner is positioned,
a T-shaped pattern having a different direction is formed at a portion where two adjacent corners are positioned, and
a cross-shaped pattern is formed at a portion where four adjacent corners are positioned.

5. The mask plate according to claim 2, wherein
the pattern region has a rectangular shape, and
the at least a part of the auxiliary region having the closed shape is positioned at an outer side of the pattern region, and the at least a part of the auxiliary region has a rectangular-shaped pattern.

6. A manufacturing method of the mask plate according to claim 1, comprising:
preparing a first sheet;
forming the pattern region and the auxiliary region on the first sheet, the auxiliary region being positioned at the outer periphery of the pattern region; and
processing the auxiliary region so that the at least a part of the auxiliary region has a thickness larger than a thickness of the pattern region.

7. The manufacturing method according to claim 6, wherein
the forming of the pattern region and the auxiliary region that is positioned at the outer periphery of the pattern region on the first sheet comprises:
patterning a pattern portion of the first sheet and forming the pattern region on the pattern portion of the first sheet; and
forming the auxiliary region at a portion other than the pattern portion on the first sheet.

8. The manufacturing method according to claim 6, wherein
the mask plate is a metal mask plate, and
the processing of the auxiliary region so that at least a part of the auxiliary region has the thickness larger than the thickness of the pattern region comprises:
coating the auxiliary region and the pattern region with a photoresist;
exposing the auxiliary region coated with the photoresist using a first mask plate to form a photoresist removing region and a photoresist remaining region of the photoresist, the photoresist removing region corresponding to the at least a part of the auxiliary region which has the thickness larger than the thickness of the pattern region and the photoresist remaining region corresponding to a remaining part of the auxiliary region and the pattern region;
removing the photoresist of the photoresist removing region to form a first electroforming substrate having a pattern identical to a pattern of the first mask plate;
performing an electroforming processing to the first electroforming substrate for growing a metal layer at the photoresist removing region by electroforming so that the at least a part of the auxiliary region has the thickness larger than the thickness of the pattern region; and
removing the photoresist of the photoresist remaining region.

9. The manufacturing method according to claim 8, wherein
the performing of the electroforming processing to the first electroforming substrate for growing the metal layer at the photoresist removing region by electroforming comprises:
placing the first electroforming substrate into an electroforming tank filled with an electroforming solution; and
electrifying the electroforming tank to grow an electroforming metal material included in the electroforming solution with the first electroforming substrate as a growing substrate until a thickness of the metal layer grown on the first electroforming substrate becomes a required thickness.

10. The manufacturing method according to claim 9, wherein
the electroforming metal material is an invar alloy or an iron.

11. The manufacturing method according to claim 9, wherein
the required thickness is 10 μm to 50 μm.

12. The manufacturing method according to claim 7, wherein
the pattern portion is a predetermined portion of the first sheet on which the pattern of the mask plate is to be formed.

13. A manufacturing method of the mask plate according to claim 1, comprising:
preparing a second sheet;
forming the pattern region and the auxiliary region on the second sheet, the auxiliary region being positioned at the outer periphery of the pattern region; and
thinning the entire pattern region and a part of the auxiliary region so that the at least a part of the auxiliary region has the thickness larger than the thickness of the pattern region or thinning the entire pattern region so that the auxiliary region has the thickness larger than the thickness of the pattern region.

14. The manufacturing method according to claim 13, wherein
the thinning of the entire pattern region and a part of the auxiliary region so that the at least a part of the auxiliary region has the thickness larger than the thickness of the pattern region comprises:
coating the pattern region and the auxiliary region with a photoresist;
exposing the pattern region and the auxiliary region coated with the photoresist using a second mask plate to form a photoresist removing region and a photoresist remaining region, the photoresist remaining region corresponding to the at least a part of the auxiliary region and the photoresist removing region corresponding to the pattern region and a remaining part of the auxiliary region;
removing the photoresist of the photoresist removing region;
thinning the photoresist removing region by etching so that the thickness of the at least a part of the auxiliary region is thicker than the thickness of the pattern region; and
removing the photoresist of the photoresist remaining region.

15. The manufacturing method according to claim 13, wherein
the thinning of the entire pattern region so that the auxiliary region has the thickness larger than the thickness of the pattern region comprises:
coating the pattern region and the auxiliary region with photoresist;
exposing the pattern region and the auxiliary region coated with the photoresist using a second mask plate to form a photoresist removing region and a photoresist remaining region, the photoresist remaining region corresponding to the auxiliary region and the photoresist removing region corresponding to the pattern region;
removing the photoresist of the photoresist removing region;
thinning the photoresist removing region by etching so that the thickness of the auxiliary region is larger than the thickness of the pattern region; and
removing the photoresist of the photoresist remaining region.

16. The manufacturing method according to claim 13, wherein
a thickness of the second sheet is 50 μm to 100 μm.

17. The manufacturing method according to claim 7, wherein
the mask plate is a metal mask plate, and
the processing of the auxiliary region so that at least a part of the auxiliary region has the thickness larger than the thickness of the pattern region comprises:
coating the auxiliary region and the pattern region with a photoresist;
exposing the auxiliary region coated with the photoresist using a first mask plate to form a photoresist removing region and a photoresist remaining region of the photoresist, the photoresist removing region corresponding to the at least a part of the auxiliary region which has the thickness larger than the thickness of the pattern region and the photoresist remaining region corresponding to a remaining part of the auxiliary region and the pattern region;
removing the photoresist of the photoresist removing region to form a first electroforming substrate having a pattern identical to a pattern of the first mask plate;
performing an electroforming processing to the first electroforming substrate for growing a metal layer at the photoresist removing region by electroforming so that the at least a part of the auxiliary region has the thickness larger than the thickness of the pattern region; and
removing the photoresist of the photoresist remaining region.

18. The manufacturing method according to claim 10, wherein
the required thickness is 10 μm to 50 μm.

19. The manufacturing method according to claims 14, wherein
a thickness of the second sheet is 50 μm to 100 μm.

20. The manufacturing method according to claims 15, wherein
a thickness of the second sheet is 50 μm to 100 μm.
